(19) United States
(12) Patent Application Publication
(10) Pub. No.: US 2025/0063824 A1
(43) Pub. Date: Feb. 20, 2025

(54) ELECTROSTATIC DISCHARGE PROTECTION DEVICE

(71) Applicant: Taiwan Semiconductor Manufacturing Co., Ltd., Hsinchu (TW)

(72) Inventors: Lin-Yu HUANG, Hsinchu (TW); Shih-Fan CHEN, Hsinchu City (TW); Sheng-Fu HSU, Hsinchu (TW); Yi-An LAI, Taipei City (TW); Chan-Hong CHERN, Palo Alto, CA (US); Cheng-Hsiang HSIEH, Taipei City (TW)

(73) Assignee: Taiwan Semiconductor Manufacturing Co., Ltd., Hsinchu (TW)

(21) Appl. No.: 18/450,475

(22) Filed: Aug. 16, 2023

(51) Int. Cl. H01L 27/02; H02H 9/04

(52) U.S. Cl. CPC H01L 27/0248; H02H 9/046

(57) ABSTRACT

This disclosure is directed to a circuit that includes a substrate, a target device on the substrate, and an electrostatic discharge (ESD) device electrically coupled to the target device. The ESD device includes an ESD detection circuit electrically coupled to a first reference voltage supply and a second reference voltage supply, an inverter circuit electrically coupled to the ESD detection circuit and configured to trigger in response to an ESD event on the first or second reference voltage supply, a rectifier circuit electrically coupled to the inverter circuit and configured to rectify a current discharged from the inverter circuit, and a transistor electrically coupled to the rectifier circuit and configured to discharge a remaining current passing through the rectifier circuit.

### BACKGROUND

Gallium nitride (GaN) is emerging as a favorable material for integrated circuit (IC) fabrication. However, GaN substrates can be limited to fabrication of n-type semiconductor devices thereon. As a result, electrostatic discharge (ESD) events in GaN structures can be difficult to mitigate.

### BRIEF DESCRIPTION OF THE DRAWINGS

Embodiments of the present disclosure are best understood from the following detailed description when read with the accompanying figures.

FIGS. 1, 2, 3A, and 3B are circuit views of power rail electrostatic discharge clamps, in accordance with some embodiments.

FIG. 4 is a flowchart for a method to mitigate an ESD event in a GaN structure, in accordance with some embodiments.

FIG. 5 is a group of voltage curves associated with an ESD event over time, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. In addition, the present disclosure may repeat reference numerals and/or letters in the various examples. This repetition does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The embodiments described herein are directed to a power rail electrostatic discharge (ESD) clamp for an integrated circuit (IC) disposed on a gallium nitride (GaN) substrate. In some embodiments, the IC includes a substrate, a target device on the substrate, and an ESD device electrically coupled to the target device. The ESD device is configured to mitigate an ESD event occurring in the structure that can damage the target device, according to some embodiments.

The ESD device can be incorporated into the IC or can be an externally connected to the IC. For example, the ESD device can be included in the IC chip design. In some embodiments, the ESD device is a stand-alone circuit. The stand-alone ESD device can be interchangeable such that the ESD device can be changed following any ESD event that may damage the ESD device. For example, the ESD device can be packaged as an external plug-in device similar to a fuse. The ESD device can be configured to attach to an external port of a device and/or system susceptible to damage from an ESD event. Similarly, the ESD device can be configured to attach to a circuit board (e.g., a bread board, a printed circuit board (PCB), a mother board, or the like).

In some embodiments, components of the ESD device (e.g., transistors, diodes, resistors, capacitors, and the like) can be replaced when damaged due to an ESD event. The ESD device can be a modular device having removably attached components that can be replaced if damaged by the ESD event. For example, if a resistor is damaged during an ESD event, the resistor can be replaced by simply removing the damaged resistor and installing a working resistor.

In some embodiments, the ESD device can include an ESD detection circuit. The ESD detection circuit can be electrically coupled to a first reference voltage supply and a second reference voltage supply, according to some embodiments. The ESD detection circuit can include at least one resistive element and at least one capacitive element. In some embodiments, the resistive element (e.g., a resistor) is electrically coupled to a first reference voltage supply (e.g., a power supply rail, which is also referred to herein as “VDD”). The capacitive element (e.g., a capacitor) can be coupled to a second reference voltage supply (e.g., ground, which is also referred to herein as “VSS”). The resistor and capacitor can be electrically coupled to each other. An ESD event occurring on the first reference voltage supply (e.g., VDD) can flow an excess current into the circuit. For example, a spike occurring on the first reference voltage supply (e.g., VDD) will behave as a voltage increase into the circuit that can elevate the gate voltage of an enhancement mode transistor device (included as part of an inverter in the circuit) and turn on the enhancement mode transistor device. Likewise, an ESD event occurring on the second reference voltage supply (e.g., VSS) can send a voltage spike into the capacitor initiating a dielectric breakdown.

In some embodiments, the ESD detection circuit (e.g., the resistor electrically coupled to the first reference voltage supply and the capacitor electrically coupled to the second reference voltage supply, where the resistor and capacitor are also electrically coupled to each other) is connected to an inverter circuit. In some embodiments, the inverter circuit includes a resistive element and a transistor device electrically coupled to one another. The resistive element can be a depletion mode transistor device or a resistor. The resistive element is electrically coupled to the first reference voltage supply (e.g., VDD). The transistor device can be an enhancement mode transistor device and electrically coupled to the second reference voltage supply (e.g., VSS).

During an ESD event, the inverter circuit electrically be triggered. For example, the enhancement mode transistor device can deactivate during the ESD event. On the other hand, the resistive element can activate during the ESD event (e.g., to allow a portion of excess current from the ESD event to pass through the resistive element). In some embodiments, the resistive element can activate in response to an ESD event on the first reference voltage supply (e.g., VDD). Conversely, the enhancement mode transistor device can deactivate in response to an ESD event on the second reference voltage supply (e.g., VSS).

In some embodiments, a rectifier circuit can be electrically coupled to the inverter circuit. The rectifier circuit can include at least one diode or a plurality of diodes connected in series to form a series rectifier circuit. The rectifier circuit can also include multiple series rectifier circuits. A first series rectifier circuit (from the multiple series rectifier circuits) can be electrically coupled to the first reference voltage supply (e.g., VDD) in a reverse bias configuration. For example, and as illustrated below, the reverse bias configuration with respect to the first reference voltage supply (e.g., VDD) can provide a stepwise rectification of at least a portion of the excess current from the ESD event as the excess current passes each reverse biased diode in the series of diodes. Similarly, a second series rectifier circuit (from the multiple series of rectifier circuits) can be electrically coupled to the second reference voltage supply (e.g., VSS) in a reverse bias configuration. The second series rectifier circuit can rectify at least a portion of the excess current from the ESD event occurring on the second reference voltage supply (e.g., VSS). The first series rectifier circuit and the second series rectifier circuit can be electrically coupled to each other. In some embodiments, the inverter circuit is electrically coupled to the first series rectifier and the second series rectifier in a forward bias configuration.

In some embodiments, a field effect transistor can be electrically coupled to the rectifier circuit. The field effect transistor can also be electrically coupled to the target device. The field effect transistor can further be electrically coupled to the first reference voltage supply (e.g., VDD) and the second reference voltage supply (e.g., VSS). The field effect transistor can be configured to discharge a remaining current from the ESD event occurring on either the first reference voltage supply (e.g., VDD) or the second reference voltage supply (e.g., VSS) passing through the rectifier circuit.

In some embodiments, the rectifier circuit protects the field effect transistor from being exposed to higher currents. In turn, the ESD device with the rectifier circuit provides a higher level of protection to the target device than an ESD device lacking the rectifier circuit.

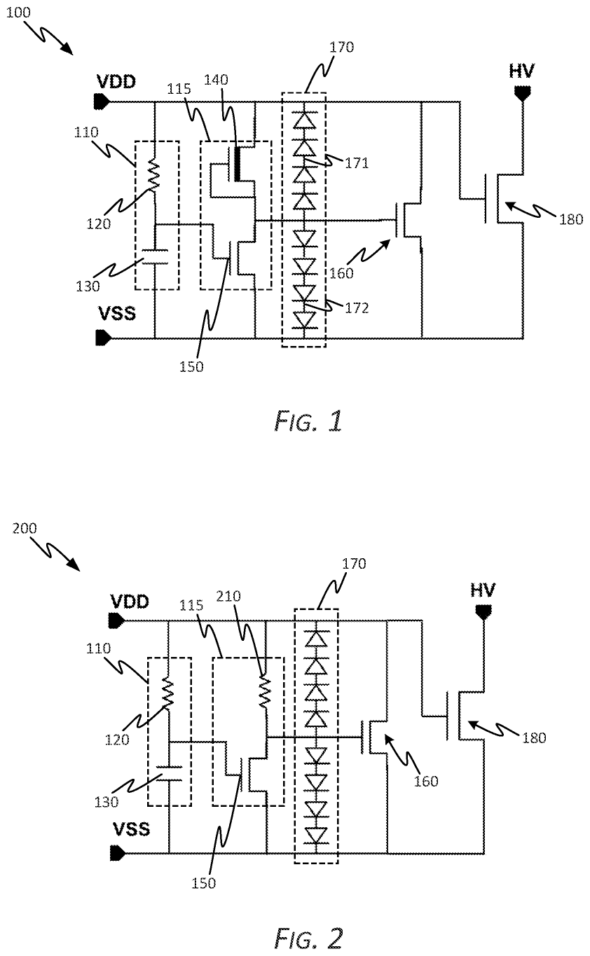

FIG. 1 is an illustration of an ESD device 100 disposed on a GaN substrate (not shown), according to some embodiments. As shown in FIG. 1, the ESD device 100 includes an ESD detection circuit 110, which includes a resistor 120 and capacitor 130. The resistor 120 and the capacitor 130 are electrically coupled to each other, with the resistor 120 electrically coupled to the first reference voltage supply (e.g., VDD) and the capacitor electrically coupled to the second reference voltage supply (e.g., VSS). The ESD device 100 includes an inverter circuit 115, which includes a resistive element 140 (e.g., a depletion mode device 140) electrically coupled to a transistor device 150 (e.g., an enhancement mode transistor device 150). The inverter circuit 115 can be a GaN inverter circuit, according to some embodiments. The ESD device 100 includes a field effect transistor 160. In some embodiments, the ESD device 100 includes a rectifier circuit 170. In some embodiments, the ESD detection circuit 110, the inverter circuit 115, the field effect transistor 160, and the rectifier circuit 170 are configured to protect the target device 180.

In some embodiments, the substrate can be a bulk semiconductor wafer or a semiconductor on insulator (SOI) wafer such as, for example, GaN on insulator. Further, the substrate can be made of an n-type semiconductor such as, for example, GaN. In other embodiments, any n-type semiconductor substrate can be used, including (i) germanium (Ge); (ii) a compound semiconductor including gallium arsenide (GaAs), gallium phosphide (GaP); (iii) an alloy semiconductor including gallium arsenide phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP); or (iv) combinations thereof. In some embodiments, the ESD device 100 described herein can be disposed on other types of semiconductor substrates, such as a p-type semiconductor substrate.

In some embodiments, the ESD device 100 can be incorporated into a complementary metal-oxide-silicon (CMOS) architecture and processing line. Additionally, GaN substrates can be integrated into CMOS production environments. While the present description refers to n-type devices, the materials and systems described herein can be subjected to process steps and equipment used in other types of fabrication processes, such as silicon (Si) based fabrication processes.

The target device 180 can be any device or system susceptible to damage from an ESD event. The target device 180 can include any semiconductor device, such as discrete components (e.g., a resistor) and electronic systems. For example, the target device 180 can be a fin FET circuit, gate-all-around (GAA) FET circuit, or any other type of circuit. The target device 180 can be any type of electronics system, such as a transmitter, a receiver, a transceiver, a graphics board, a mother board, a processor, a memory device, a signal processor, an amplifier, or a sensor.

Referring to FIG. 1, the ESD detection circuit 110 is configured to trigger upon the onset of an ESD event. For example, during an ESD event occurring on the second reference voltage supply (e.g., VSS), the capacitor 130 in the ESD detection circuit 110 can discharge (e.g., short circuit caused by an incoming current that elevates a potential on the capacitor plate closest to the second reference voltage (e.g., VSS; the bottom plate of the capacitor). The capacitor 130 can have a capacitance in the range from about 1 pF to about 1 nF (e.g., 1 pF, 10 pF, 100 pF, or 1 nF), according to some embodiments. Other capacitance ranges/values are within the scope of the present disclosure. Further, the resistor 140 in the ESD detection circuit 110 can have a resistance in the range from about 1 kΩ to about 10 kΩ (e.g., about 1 kΩ to about 9 kΩ, about 2 kΩ to about 10 kΩ, about 3 kΩ to about 7 kΩ, or about 1 kΩ to about 5 kΩ). For example, the ESD detection circuit 110 can have a resistance of about 1 kΩ, about 2 kΩ, about 3 kΩ, about 4 kΩ, about 5 kΩ, about 6 kΩ, about 7 kΩ, about 8 kΩ, about 9 kΩ, or about 10 kΩ, according to some embodiments.

During an ESD event occurring on the first reference voltage supply (e.g., VDD), the resistor 120 will pass current from the ESD event on the first reference voltage supply (e.g., VDD). For example, the resistor 120 can exhibit either a voltage increase or a voltage decrease depending on the source of the ESD event. For example, the resistor 120 can exhibit a voltage increase across it when the ESD event occurs on the first reference voltage supply (e.g., VDD) and a voltage decrease across it when the ESD event occurs on the second reference voltage supply (e.g., VSS). In some embodiments, the resistor 120 and the capacitor 130 are electrically coupled to function in concert to detect an ESD event.

A response time for the ESD detection circuit 110 can be up to about 10 nanoseconds (ns), according to some embodiments. As clock speeds increase in microchip technology, reduced response times are necessary to protect the target device 180. Thus, a response time of up to about 10 ns or less is important. In some embodiments, the response time can be about 1 ns, 2 ns, 3 ns, 4 ns, 5 ns, 6 ns, 7 ns, 8 ns, 9 ns, or 10 ns. Other response times are within the scope of the present disclosure. The response time can be based on the RC-delay set by the resistor 120 and the capacitor 130.

The inverter circuit 115 can be electrically coupled to the ESD detection circuit 110. For example, both the resistive element 140 (e.g., the depletion mode device 140) and the transistor device 150 (e.g., enhancement mode transistor device 150) can be electrically coupled to the ESD detection circuit 110 at a common circuit node, as shown in FIG. 1. Further, the resistive element 140 (e.g., the depletion mode device 140) can be electrically coupled to the first reference voltage supply (e.g., VDD). The transistor device 150 (e.g., the enhancement mode transistor device 150) can be electrically coupled to the second reference voltage supply (e.g., VSS).

The resistive element 140 (e.g., the depletion mode device 140) triggers during ESD events occurring on the first reference voltage supply (e.g., VDD), according to some embodiments. The depletion mode device 140 is in an always on condition until an ESD event occurs. In some embodiments, the depletion mode device 140 can deactivate (e.g., turn off) when excess current passes through the resistor 120 (e.g., an ESD event). The excess current can show as a voltage rise across the resistor. A voltage rise in a magnitude range from about 0.5 V to about 3 V (e.g., about 1 V to about 3 V, about 0.5 V to about 2.5 V, or about 1 V to about 2.5 V) can trigger the deactivation of the depletion mode device. Other voltage ranges/values are within the scope of the present disclosure. For example, the depletion mode device 140 can trigger at a voltage of 0.5 V, 1 V, 1.5 V, 2 V, 2.5 V, or 3 V.

The transistor device 150 (e.g., the enhancement mode transistor device 150) can trigger during ESD events occurring on the second reference voltage supply (e.g., VSS), according to some embodiments. The enhancement mode transistor device 150 is activated (e.g., turned on) when a voltage discharge from the capacitor 130 is in a range from about 1 V to about 3 V (e.g., about 1 V to about 2 V, or about 2 V to about 3 V), according to some embodiments. Other activation voltage ranges/values are within the scope of the present disclosure. The enhancement mode transistor device 150 can be activated when the voltage across the resistor 120 is 1 V, 1.1 V, 1.2 V, 1.3 V, 1.4 V, 1.5 V, 1.6 V, 1.7 V, 1.8 V, 1.9 V, 2 V, 2.1 V, 2.2 V, 2.3 V, 2.4 V, 2.5 V, 2.6 V, 2.7 V, 2.8 V, 2.9 V, or 3 V. The gate voltage on the enhancement mode transistor device 150 can increase when the voltage across the resistor (e.g., the source voltage resulting from the ESD event) is greater than the threshold voltage of the transistor gate.

In some embodiments, the resistive element 140 (e.g., the depletion mode device 140) and the transistor device 150 (e.g., the enhancement mode transistor device 150) are n-type devices, thus suitable for GaN technology. Further, including both the resistive element 140 (e.g., the depletion mode device 140) and the transistor device 150 (e.g., the enhancement mode transistor device 150) provides protection from ESD events occurring on either the first reference voltage supply (e.g., VDD) or the second reference voltage supply (e.g., VSS).

In some embodiments, the rectifier circuit 170 is electrically coupled to the ESD detection circuit 110, and the inverter circuit 115. The rectifier circuit 170 is also connected to the first reference voltage supply (e.g., VDD) and the second reference voltage supply (e.g., VSS). The rectifier circuit 170 can include a first series rectifier circuit 171 electrically coupled to the first reference voltage supply (e.g., VDD) and a second series rectifier circuit 172 electrically coupled to the second reference voltage supply (e.g., VSS). The first series rectifier circuit 171 is arranged in reverse bias configuration with respect to the first reference voltage supply (e.g., VDD). The second series rectifier circuit 172 is arranged in a reverse bias configuration with respect to the second reference voltage supply (e.g., VSS). When the resistive element 140 (e.g., the depletion mode device 140) is deactivated or the transistor device 150 (e.g., the enhancement mode transistor device 150) is activated, the rectifier circuit 170 is activated. The rectifier circuit 170 includes at least one diode, and may include any number of diodes according to the magnitude of an anticipated ESD event. Accordingly, the number of diodes in the series of diodes is proportional to a rectified magnitude of the ESD event. For example, when each diode of the first series rectifier circuit 171 or the second series rectifier circuit 172 is rated at about 1.5 V, four diodes in the series rectifier circuits can suppress about a 6 V ESD event.

In some embodiments, the field effect transistor 160 can be configured to have a maximum gate breakdown voltage in a range from about 10 V to about 15 V (e.g., about 10 V to about 14 V, about 11 V to about 15 V, or about 11 V to about 14 V). Other voltage ranges/values are within the scope of the present disclosure. For example, the maximum gate breakdown voltage can be about 10 V, about 11 V, about 12 V, about 13 V, about 14 V, or about 15 V. In some embodiments, the field effect transistor 160 can be configured to turn on at about a 6 V gate voltage. The field effect transistor 160 can turn on at voltages less than the gate breakdown voltage (e.g., from about 6 V to about 10 V), allowing a reduced rise time on the gate of the field effect transistor 160. The 6 V breakdown enables the ESD device 100 to have a shorter response time and thus a faster ESD protection time. For example, the response time is dependent on the rise time of the gate of the field effect transistor 160, which can be less than or equal to 10 nanoseconds (ns). For example, the rise time of the field effect transistor 160 gate can be up to about 10 ns, up to about 9 ns, up to about 8 ns, up to about 7 ns, up to about 6 ns, up to about 5 ns, up to about 4 ns, up to about 3 ns, up to about 2 ns, or up to about 1 ns. The ESD device 100 can mitigate an ESD event in less than or equal to 10 ns.

Additionally, the ESD device 100 described herein provides a more robust circuit across different operation voltages in GaN substrate technology. To increase breakdown voltage, in the inverter circuit 115, the resistive element 140 (e.g., the depletion mode device 140) and/or the transistor device (e.g., the enhancement mode transistor device 150) can be tailored by modifying the drift region spanning the source and drain of these devices. Modifications to the hole and/or electron mobility in the drift region spanning the source and drain of the transistor devices include doping the drift region during fabrication and/or changing the length scale of the drift region. For example, a 650 V GaN high mobility electron transistor (E HEMT) power switch with a modified gate and source connection for a high voltage rectifier can sustain up to 900 V. Modifications to the drift region spanning the source and drain of the depletion mode device 140 and/or the enhancement mode device 150 can reduce device and diode damage risk and provide operation at various voltages. Thus, the ESD device 100 can be constructed to withstand ultra-high voltage applications by incorporating an ultra-high voltage enhancement mode transistor device, an ultra-high voltage depletion mode device, and an ultra-high voltage series rectifier.

FIG. 2 is an illustration of an ESD device 200, according to some embodiments. Here, the resistive element 140 (e.g., the depletion mode device 140) of FIG. 1 is replaced with a resistor 210, which can reduce the overall size of the ESD device 200 without compromising the ESD protection. In some embodiments, the resistor 210 can have a resistance of at least about 10 mΩ (e.g., from about 10 mΩ to about 100 mΩ, from about 20 mΩ to about 100 mΩ, from about 10 mΩ to about 90 mΩ, from about 20 mΩ to about 80 mΩ, or about 10 mΩ to about 70 m (2). Other resistance ranges/values are within the scope of the present disclosure. The resistance of the resistor 210 can be at least 10 mΩ, at least 15 mΩ, at least 20 mΩ, at least 25 mΩ, at least 30 mΩ, at least 35 mΩ, at least 40 mΩ, at least 45 mΩ, at least 50 mΩ, at least 55 mΩ, at least 60 mΩ, at least 65 mΩ, at least 70 mΩ, at least 75 mΩ, at least 80 mΩ, at least 85 mΩ, at least 90 mΩ, at least 95 mΩ, or at least 100 mΩ.

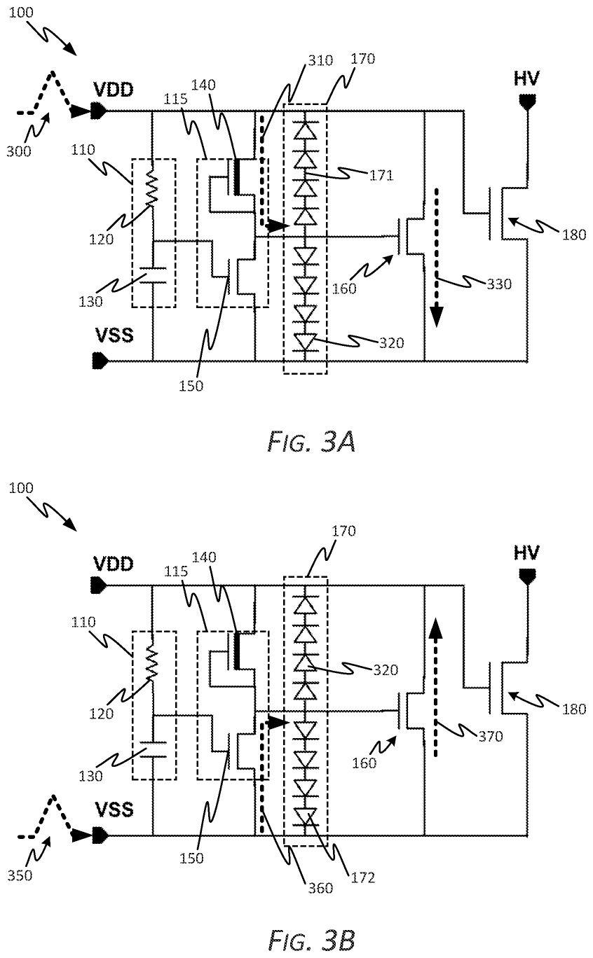

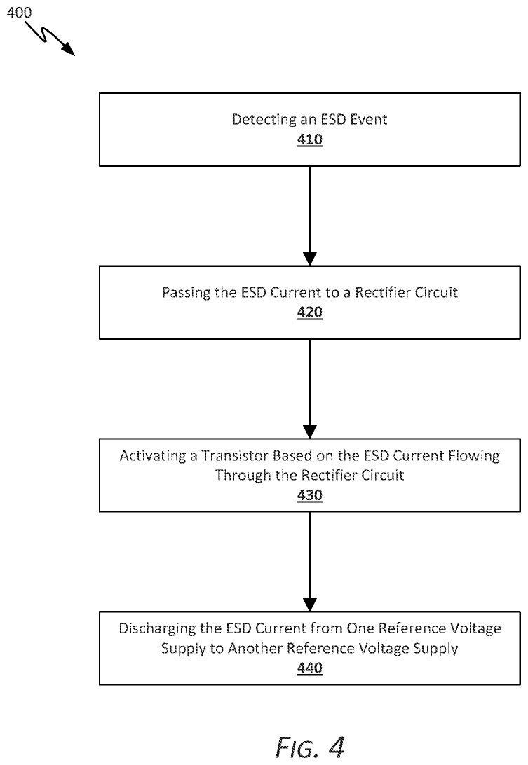

Referring to FIGS. 3 and 4, a method 400 of protecting the target device 180 and annotated circuit diagrams (FIGS. 3A and 3B) to facilitate in the explanation of the method are illustrated, according to some embodiments. During an ESD event occurring on the first reference voltage supply (e.g., VDD), the detection circuit 110 exhibits a voltage increase across the resistor 120. The detection circuit 110 directs excess circuit current to the resistive element 140 (e.g., the depletion mode device 140). In one example shown in FIG. 3A, the ESD event can be about a 10 V static discharge from the first reference voltage supply (e.g., VDD), which is represented by an ESD current spike 300. The resistor 120 exhibits a voltage increase across it. The resistive element 140 (e.g., the depletion mode device 140) is deactivated and the excess current from the ESD event occurring on the first reference voltage supply (e.g., VDD) is directed to the first series rectifier circuit 171 along a current path 310. In some embodiments, the first series rectifier circuit 171 includes four diodes 320. In some embodiments, each diode 320 is rated at about 1.5 V, thus the group of four diodes 320 reduces the ESD event occurring on the first reference voltage supply (e.g., VDD) by about 6 V. The remainder of the excess current is directed to the field effect transistor 160 and is eliminated through the field effect transistor 160 along a current path 330. In the present example, the remaining about 4 V from the ESD event occurring on the first reference voltage supply (e.g., VDD) is directed to the gate of the field effect transistor 160. The target device 180 is not exposed to current from the ESD event occurring on the first reference voltage supply (e.g., VDD) or any current discharged from the capacitor 130 in the detection circuit 110.

During an ESD event occurring on the second reference voltage supply (e.g., VSS), the detection circuit 110 exhibits a discharge from the capacitor 130. The detection circuit 110 directs the discharged current to the transistor device 150 (e.g., the enhancement mode transistor device 150). In one example shown in FIG. 3B, the ESD event can be about a 10 V static discharge from the second reference voltage supply (e.g., VSS). The capacitor 130 exhibits a current discharge when sufficient charge builds up on the bottom plate of the capacitor 130. The discharge from the capacitor 130 can flow to the gate of the enhancement mode transistor device 150. The enhancement mode transistor device 150 is activated and the excess current from the ESD event occurring on the second reference voltage supply (e.g., VSS) is directed to the second series rectifier circuit 172 along a current path 360. In some embodiments, the second series rectifier circuit 172 includes four diodes 320. In some embodiments, each diode 320 is rated at about 1.5 V, thus the group of four diodes 320 reduces the ESD event occurring on the second reference voltage supply (e.g., VSS) by about 6 V. The remainder of the excess current is directed to the field effect transistor 160 and is eliminated through the field effect transistor 160 along a current path 370. In the present example, the remaining about 4 V from the ESD event occurring on the second reference voltage supply (e.g., VSS) is directed to the gate of the field effect transistor 160. The target device 180 is not exposed to current from the ESD event occurring on the second reference voltage supply (e.g., VSS).

FIG. 4 is a flowchart of method 400 illustrating operations of an ESD device following an ESD event, according to some embodiments. For illustrative purposes, the operations of method 400 will be described with reference to FIGS. 1, 2, 3A, and 3B. The operations of method 400 can be performed in a different order or not performed depending on specific applications. Further, it is understood that additional operations can be provided before, during, and after method 400, and that other operations may only be briefly described herein

In operation 410, an ESD is detected. For example, the ESD event can enter the ESD device 100 through either the first reference voltage supply (e.g., VDD) or the second reference voltage supply (e.g., VSS). According to some embodiments, detecting the ESD event is performed by the detection circuit 110. Detecting the ESD event can be performed by monitoring a voltage drop across the resistor 120, a voltage increase across the resistor 120, or a discharge from the capacitor 130. The detection circuit 110 is configured to sense an ESD event from either the first reference voltage supply (e.g., VDD) or the second reference voltage supply (e.g., VSS). In some embodiments, the ESD event occurring on the first reference voltage supply (e.g., VDD) can be detected by the detection circuit 110 and passed to the inverter circuit 115, particularly, the resistive element 140 (e.g., the depletion mode device 140 of FIG. 1 or the resistor 210 of FIG. 2). Conversely, an ESD event occurring on the second reference voltage supply (e.g., VSS) can be detected as a discharge from the capacitor 130.

In operation 420, an ESD current is passed to a rectifier circuit. Regardless of the ESD event occurring on the first reference voltage supply (e.g., VDD) or the second reference voltage supply (e.g., VSS), the current passed through the detection circuit 110 and the inverter circuit 115 will pass to the rectifier circuit 170. In the case of the ESD event occurring on the first reference voltage supply (e.g., VDD), excess current from the ESD event passing through the detection circuit 110 and the inverter circuit 115 can be rectified by the rectifier circuit 170. In some embodiments, the ESD event occurring on the first reference voltage supply (e.g., VDD) can be rectified by the first series rectifier circuit 171. Likewise, an ESD event occurring on the second reference voltage supply (e.g., VSS) can be rectified by the second series rectifier circuit 172. Rectifying the ESD event is performed by passing the excess current from the ESD event through at least one diode within the ESD device 100 arranged in a reverse bias configuration with respect to the source of the excess current. In other words, an ESD event occurring on the first reference voltage supply (e.g., VDD) will be rectified by at least one diode of the rectifier circuit 170 arranged in a reverse bias configuration with respect to the first reference voltage supply (e.g., VDD). Similarly, an ESD event occurring on the second reference voltage supply (e.g., VSS) will be rectified by at least one diode of the rectifier circuit 170 arranged in a reverse bias configuration with respect to the second reference voltage supply (e.g., VSS). Particularly, an ESD event occurring on the first reference voltage supply (e.g., VDD) can be rectified by the first series rectifier circuit 171, and an ESD event occurring on the second reference diode VSS can be rectified by the second series rectifier circuit 172.

In operation 430, a transistor (e.g., the field effect transistor 160) is activated based on the ESD current flowing through the rectifier circuit. The rectified current from the ESD event on either of the first reference voltage supply (e.g., VDD) or the second reference voltage supply (e.g., VSS) can be passed to the field effect transistor 160.

In operation 440, the ESD current flows through a transistor (e.g., the field effect transistor 160) from one reference voltage supply to another reference voltage supply. Passing the rectified current (e.g., the remaining current from the ESD event) corresponds to activating the field effect transistor 160. Activating the field effect transistor 160 includes flowing ESD current through the field effect transistor 160 from the first reference voltage supply (e.g., VDD) to the second reference voltage supply (e.g., VSS) in the event of an ESD event occurring on the first reference voltage supply. Likewise, activating the field effect transistor 160 includes flowing ESD current through the field effect transistor 160 from the second reference voltage supply (e.g., VSS) to the first reference voltage supply (e.g., VDD) in the event of an ESD event occurring on the second reference voltage supply.

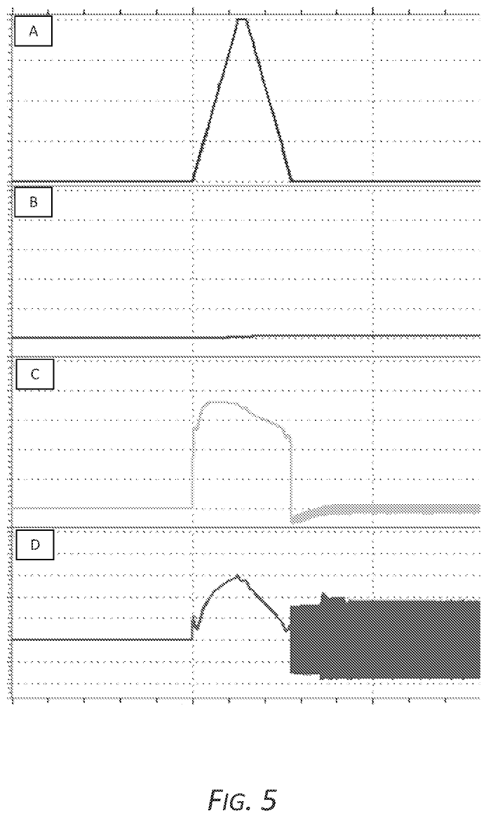

FIG. 5 illustrates the voltage profiles during an ESD event, according to some embodiments. Curve A illustrates a voltage spike (e.g., about 2 kV) on the first reference voltage supply (e.g., VDD), in which the transistor device 150 (e.g., the enhancement mode transistor device 150) will activate and the resistive element 140 (e.g., the depletion mode device 140) will deactivate. The ESD detection circuit 110 (curve B in FIG. 5) shows either a voltage increase (e.g., about 0.5 V) across the resistor 120 or the capacitor 130, and the rectifier circuit 170 (curve C in FIG. 5). A spike is directed to the rectifier circuit 170 and a reduced voltage is directed to the field effect transistor 160 (curve D in FIG. 4). Curve D illustrates the current flow through the field effect transistor 160.

The ESD device 100 can be incorporated into the IC or can be an externally connected to the IC. For example, the ESD device 100 can be included in the IC chip design. In some embodiments, the ESD device 100 is a stand-alone circuit. The stand-alone ESD device 100 can be interchangeable such that the ESD device 100 can be changed following any ESD event that may damage the ESD device 100. For example, the ESD device 100 can be packaged as an external plug-in device similar to a fuse. The ESD device 100 can be configured to attach to an external port of a device and/or system susceptible to damage from an ESD event. Similarly, the ESD device 100 can be configured to attach to a circuit board (e.g., a bread board, a printed circuit board (PCB), a mother board, or the like).

In some embodiments, components of the ESD device 100 (e.g., transistors, diodes, resistors, capacitors, and the like) can be replaced when damaged due to an ESD event. The ESD device 100 can be a modular device having removably attached components that can be replaced if damaged by the ESD event. For example, if a resistor is damaged during an ESD event, the resistor can be immediately replaced by simply removing the damaged resistor and installing a working resistor.

In some embodiments, a circuit includes a substrate, a target device on the substrate, and an electrostatic discharge (ESD) device electrically coupled to the target device. The ESD device 100 includes an ESD detection circuit electrically coupled to a first reference voltage supply and a second reference voltage supply, an inverter circuit electrically coupled to the ESD detection circuit and configured to trigger in response to an ESD event on the first or second reference voltage supply, a rectifier circuit electrically coupled to the inverter circuit and configured to rectify a current discharged from the inverter circuit, and a transistor electrically coupled to the rectifier circuit and configured to discharge a remaining current passing through the rectifier circuit.

In some embodiments, a circuit includes a gallium nitride (GaN) substrate, a target device, and an electrostatic discharge (ESD) device electrically coupled to the target device. The ESD device 100 includes an ESD detection circuit electrically coupled to a first reference voltage electrode and a second voltage electrode, a GaN inverter circuit including an enhancement mode transistor device and a resistive element. The GaN inverter circuit is electrically coupled to the ESD detection circuit and the GaN inverter circuit is configured to trigger in response to an ESD event on the first or second reference voltage supply. The ESD device 100 also includes a rectifier circuit electrically coupled to the GaN inverter circuit and configured to rectify current discharged from the GaN inverter circuit and a field effect transistor (FET) electrically coupled to the rectifier circuit and configured to discharge a remaining current passing through the rectifier circuit

In some embodiments, a method includes detecting an electrostatic discharge (ESD) current on a reference voltage supply, passing the ESD current to a rectifier circuit, activating a transistor based on the ESD current flowing through the rectifier circuit, and discharging, through the transistor, the ESD current from a first reference voltage supply to a second reference voltage supply.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a substrate;
a target device on the substrate; and
an electrostatic discharge (ESD) device electrically coupled to the target device, the ESD device comprising:
an ESD detection circuit electrically coupled to a first reference voltage supply and a second reference voltage supply;
an inverter circuit electrically coupled to the ESD detection circuit and configured to trigger in response to an ESD event on the first reference voltage supply or the second reference voltage supply;
a rectifier circuit electrically coupled to the inverter circuit and configured to rectify a current discharged from the inverter circuit; and
a transistor electrically coupled to the rectifier circuit and configured to discharge a remaining current passing through the rectifier circuit.

2. The circuit of claim 1, wherein the substrate comprises an n-type substrate.

3. The circuit of claim 1, wherein the ESD detection circuit comprises a resistor electrically coupled a capacitor.

4. The circuit of claim 1, wherein the ESD detection circuit is electrically coupled to the inverter circuit.

5. The circuit of claim 1, wherein the inverter circuit comprises an enhancement mode transistor device electrically coupled to a resistive element.

6. The circuit of claim 1, wherein the inverter circuit is electrically coupled to the rectifier circuit.

7. The circuit of claim 1, wherein the rectifier circuit comprises a diode configured to rectify a current from the ESD event.

8. The circuit of claim 1, wherein the rectifier circuit comprises a plurality of diodes arranged in a reverse bias configuration.

9. The circuit of claim 1, wherein the transistor is electrically coupled to the target device.

10. A circuit, comprising:
a gallium nitride (GaN) substrate;
a target device; and
an electrostatic discharge (ESD) device electrically coupled to the target device, the ESD device comprising:
an ESD detection circuit electrically coupled to a first reference voltage supply and a second reference voltage supply;
a GaN inverter circuit comprising an enhancement mode transistor device and a resistive element, wherein the GaN inverter circuit is electrically coupled to the ESD detection circuit, and wherein the GaN inverter circuit is configured to trigger in response to an ESD event on the first reference voltage supply or the second reference voltage supply;
a rectifier circuit electrically coupled to the GaN inverter circuit and configured to rectify current discharged from the GaN inverter circuit; and
a field effect transistor (FET) electrically coupled to the rectifier circuit and configured to discharge a remaining current passing through the rectifier circuit.

11. The circuit of claim 10, wherein the ESD detection circuit comprises a resistor electrically coupled to a capacitor.

12. The circuit of claim 10, wherein the GaN inverter circuit, wherein the enhancement mode transistor device electrically coupled to the resistive element.

13. The circuit of claim 10, wherein the rectifier circuit comprises a plurality of diodes arranged in a reverse bias configuration.

14. The circuit of claim 10, wherein the FET is electrically coupled to the target device.

15. A method, comprising:
detecting an electrostatic discharge (ESD) current on a reference voltage supply;
passing the ESD current to a rectifier circuit;
activating a transistor based on the ESD current flowing through the rectifier circuit; and
discharging, through the transistor, the ESD current from a first reference voltage supply to a second reference voltage supply.

16. The method of claim 15, further comprising triggering an inverter circuit by flowing current through a resistive element or activating an enhancement mode transistor device.

17. The method of claim 15, wherein activating the transistor comprises flowing current through at least one diode.

18. The method of claim 17, wherein flowing the current through the at least one diode comprises flowing current through a plurality of diodes arranged in a reverse bias configuration.

19. The method of claim 18, wherein flowing the current through the plurality of diodes arranged in the reverse bias configuration comprises rectifying the ESD current.

20. The method of claim 19, wherein a number of the plurality of diodes is proportional to a rectified magnitude of the ESD current.
